(19) United States
(12) Patent Application Publication
(10) Pub. No.: US 2019/0182969 A1
(43) Pub. Date: Jun. 13, 2019

(54) FLEXIBLE DISPLAY AND IT FABRICATING METHOD AND DISPLAY DEVICE

(71) Applicant: FLEXIBLE DISPLAY AND IT FABRICATING METHOD AND DISPLAY DEVICE, Wuhan (CN)

(72) Inventor: Jifeng CHEN, Shenzhen (CN)

(21) Appl. No.: 15/951,990

(22) Filed: Apr. 12, 2018

Related U.S. Application Data
(63) Continuation of application No. PCT/CN2018/071302, filed on Jan. 4, 2018.

(30) Foreign Application Priority Data
Dec. 13, 2017 (CN) 201711331845.9

(51) Int. Cl. H05K 5/00; H05K 1/02; H05K 5/06; H05K 7/20; H05K 3/28

(52) U.S. Cl. CPC H05K 5/0017; H05K 1/028; H05K 3/284; H05K 7/20218; H05K 3/285; H05K 5/061

(57) ABSTRACT

The present disclosure provides a flexible display divided into at least two non-bending regions and bending regions connecting two adjacent non-bending regions. The flexible display includes a backplane, a display panel and a cover plate, the peripheral area of the back plate and the peripheral area of the cover plate are connected through a sealant and a sealed receiving cavity is formed between the back plate and the cover plate, and the display panel is arranged on the back plate and is accommodated in the receiving cavity. Optically clear oil is provided between a region of the display panel corresponding to the bending zone and the cover plate. When the flexible display is folded, the flexible display can be prevented from being damaged due to the change of the neutral plane of the display panel, and the light-emitting efficiency of the display panel can be improved.

### RELATED APPLICATIONS

This application is a continuation application of PCT Patent Application No. PCT/CN2018/071302, filed Jan. 4, 2018, which claims the priority benefit of Chinese Patent Application No. 201711331845.9, filed Dec. 23, 2017, which is herein incorporated by reference in its entirety.

### FIELD OF THE DISCLOSURE

The present disclosure relates to a display and its fabricating method, and more particularly, to a flexible display and its fabricating method, and a display device with a flexible display.

### BACKGROUND

With the ever-changing technology, the application of display in people's lives is also more and more widely used. The display usually includes a backplane, a middle frame, a display component and a cover plate. In the conventional hard-type display, the display component is usually attached to the cover plate. However, when the structure is applied to most of the currently available foldable displays, the display is folded, a partial area of the display assembly may be over-stressed due to a neutral surface offset of the display, thereby being damaged or even invalidated. In order to avoid the above problem, in the prior art, the display component is usually pasted on the backplane such that a gap is formed between the display component and the cover, so that the stress between the display component and the cover do not pass each other. However, the above structure also reduces the light output efficiency of the display, thereby affecting the optical quality of the display.

### SUMMARY

In view of this, the present disclosure provides a flexible display in order to effectively solve the above technical problems.

In addition, it is also necessary to provide a fabricating method of the flexible display and a display device with the flexible display.

A flexible display is divided into at least two non-bent regions and a bent region connecting two adjacent non-bent regions, the flexible display comprising a backplate, a display panel and a cover plate sequentially laminated in order, the peripheral area of the backplate and the peripheral area of the cover plate are connected through a sealant and form a sealed receiving cavity between the backplate and the cover plate, the display panel is set on the back plate and received in the receiving cavity, and an optically clear oil is provided between an area of the display panel corresponding to the bending region and the cover plate.

Further, an optically clear oil is disposed between the area of the display panel corresponding to the bending region and the sealant, and the fluidity of the optically clear oil facilitates heat dissipation of the flexible display so as to prevent the flexible display locally overheated.

Further, an optically clear oil is disposed between a region corresponding to the non-bending region of the display panel and the cover plate and between a region corresponding to the non-bending region of the display panel and the sealant.

Further, an optically clear oil is disposed between a region of the display panel corresponding to the bending region and the backplane.

A fabricating method of the flexible display, the flexible display is divided into at least two non-bending regions and bending regions connecting two adjacent non-bending regions, and the method for fabricating the flexible display device includes the following steps: providing a backplate attached with a display panel, the display panel comprising a non-folding region corresponding to the non-bending region and a folding region corresponding to the bending region; dispensing glue along the peripheral region of the backplate to form an uncured or semi-cured sealant, so as to make the sealant and the backplate to round setting and form a receiving slot; to receive the display panel, and the height of the sealant is greater than the height of the display panel; filling at least optically clear oil in an area of the receiving slot corresponding to the folding region, so that the optically clear oil at least covers the folding region; and covering a side of the sealant away from the back plate with a cover plate and curing the sealant, so as to seal the receiving slot to form a receiving cavity, for obtained the flexible display.

Further, the step of “filling at least optically clear oil in an area of the receiving slot corresponding to the folding region, so that the optically clear oil at least covers the folding region” is specifically filling optically clear oil so as to cover the entire display panel.

Further, the step of “filling at least optically clear oil in an area of the receiving slot corresponding to the folding region, so that the optically clear oil at least covers the folding region” is specifically coating an optically clear oil on at least a portion of the receiving slot corresponding to the unfolded area, so that the optically transparent adhesive covers the corresponding unfolded area; filling an optically clear oil in an area of the receiving slot corresponding to the folding region and the area of the receiving slot corresponding to the non-folding region wherein the optically clear oil is not coated, so that the optically clear oil covers the folding region and the non-folding region which are not covered by the optically clear oil.

A fabricating method of a flexible display, the flexible display is divided into at least two non-bending regions and a bending region of connecting two adjacent non-bending regions, and the fabricating method of the flexible display comprises the following steps: providing a backplate, and dispensing glue along the peripheral region of the back plate to form an uncured or semi-cured sealant, so as to make the sealant and the back plate to round setting and form a receiving slot; filling the receiving slot with the optically clear oil, and placing a display panel with a height less than the depth of the receiving slot, so that the display panel is covered with the transparent optical oil; and covering a cover plate on a side of the sealant away from the backplate and curing the sealant so as to seal the receiving slot to form a receiving cavity, for obtaining the flexible display.

A display device, comprising a flexible display as described above.

In the flexible display according to the present disclosure, an optically clear oil is provided at least between a region of the display panel corresponding to the bending region and the cover plate. So when the flexible display is bent, the stress between the display panel and the cover plate does not transmit to each other, and the display panel, the cover plate and the optically clear oil respectively have a neutral plane, so that the position of the neutral plane of the display panel does not change after the flexible display is formed, to avoid damage caused by the change of the neutral plane position of the display panel when the flexible display is folded. Furthermore, an optically clear oil is provided at least between a region of the display panel corresponding to the bending region and the cover plate. and the total reflectivity of light at each interface is also reduced, thereby promote the light output of the display panel effectiveness.

### BRIEF DESCRIPTION OF THE DRAWINGS

To describe the technical solutions in the embodiments of the present disclosure or in the prior art more clearly, the following briefly introduces the accompanying drawings required for describing the embodiments or the prior art. Apparently, the accompanying drawings in the following description are merely some embodiments of the present disclosure. For those skilled in the art, other drawings may be obtained based on these drawings under the premise of without any creative work.

FIG. 1 is a schematic structural diagram of a flexible display according to an embodiment of the present disclosure.

FIG. 2 is a schematic cross-sectional view of a flexible display according to an embodiment of the present disclosure.

FIG. 3 is a schematic cross-sectional view of a flexible display according to another embodiment of the present disclosure.

FIG. 4 is a flowchart of a fabricating method of a flexible display according to an embodiment of the present disclosure.

FIG. 5 is a schematic cross-sectional view of a back plate bonded with a display panel used in the fabricating method of the flexible display shown in FIG. 4.

FIG. 6 is a schematic cross-sectional view of forming the sealant and the receiving slot on the back plate shown in FIG. 5.

FIG. 7 is a schematic cross-sectional view of filling optically clear oil in the receiving slot that shown in FIG. 6.

FIG. 8 is a flowchart of a fabricating method of the flexible display of another embodiment of the present disclosure.

FIG. 9 is a schematic cross-sectional view of the back plate with the sealant and the receiving slot used in the fabricating method of the flexible display shown in FIG. 8.

FIG. 10 is a cross-sectional schematic diagram of filling optically clear oil in the receiving slot that shown in FIG. 9.

FIG. 11 is a display device with a flexible display of an embodiment of the present disclosure.

### DETAILED DESCRIPTION OF PREFERRED EMBODIMENTS

The technical solutions in the embodiments of the present disclosure will be described clearly and completely hereinafter with reference to the accompanying drawings in the embodiments of the present disclosure. Apparently, the described embodiments are merely a part but not all embodiments of the present disclosure. All other embodiments obtained by persons of ordinary skill in the art based on the embodiments of the present disclosure without creative efforts shall fall within the protection scope of the present disclosure.

Underneath will combine FIG. 1 to 11 and the embodiments to further describe in detail of the flexible display 100 provided by the technical solution and the fabricating method, and the display device 200 provided with the flexible display 100.

Referring to FIG. 1 to 3, a flexible display 100 according to a preferred embodiment of the present disclosure, including stacked sequentially a back plate 10, a display panel 20 and a cover plate 30. The peripheral region of the back plate 10 and the peripheral region of the cover plate 30 are connected by the sealant 40 and a sealed receiving cavity 50 is formed between the back plate 10 and the cover plate 30. The display panel 20 is received in the receiving cavity 50.

In the present embodiment, the sealant 40 may be a UV-curable adhesive or a thermosetting adhesive.

The flexible display 100 is divided into at least two non-bending regions 101 and a bending region 103 connecting two adjacent non-bending regions 101.

An optically clear oil 60 is accommodated between a region of the display panel 20 corresponding to the bending region 103 and the cover plate 30. An optically clear oil (not shown) and/or an optically clear adhesive (not shown) may also be disposed between a region of the display panel 20 corresponding to the non-bending region 101 and the cover plate 30.

In the present embodiment, an optically clear oil 60 is accommodated between a region of the display panel 20 corresponding to the bending region 103 and the sealant 40.

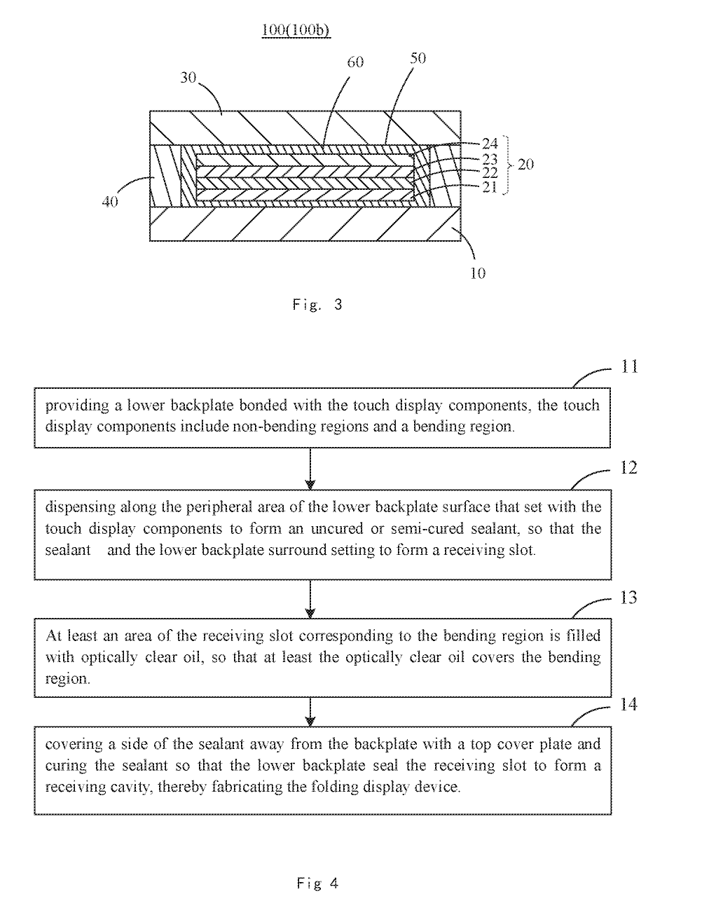

In the present embodiment, the display panel 20 is attached to the back plate 10. In other embodiments, referring to FIG. 3, the display panel 20 is disposed at a distance from the back plate 10, the optically clear oil is accommodated between a region of the display panel 20 corresponding to the bending region 103. Similarly, optically clear oil may also be accommodated between the region of the display panel 20 corresponding to the non-bending region 103 and the back 10. The fluidity of the optically clear oil 60 facilitates the conduction and dissipation of heat of the flexible display 100 so as to prevent the flexible display 100 from being partially overheated.

In this embodiment, the display panel 20 includes a substrate 21, a display panel 22, a touch panel 23 and a polarizer 24 stacked in this order along the stacking direction of the back plate 10 and the cover plate 30. The display panel 22 may be a liquid crystal display panel, an OLED display panel, or the like.

Referring to FIG. 1 to 2 and FIG. 4 to 7, a preferred embodiment of the present disclosure further provides a fabricating method of a flexible display 100a, which is divided into at least two non-bending regions 101 and adjoining two bending regions 103 of the non-bending region 101, and the fabricating method of the flexible display 100a includes the following steps:

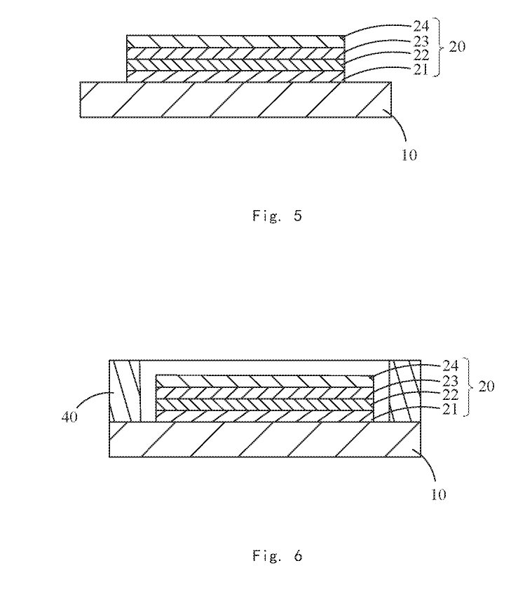

In step S11, referring to FIG. 5, a back plate 10 bonding with a display panel 20 is provided.

The display panel 20 is divided into a non-folding region (not shown) corresponding to the non-bending region 101 and a folding region (not shown) corresponding to the bending region 103.

In the embodiment, the display panel 20 includes a substrate 21, a display panel 22, a touch panel 23 and a polarizer 24 that are sequentially stacked. The substrate 21 is bonded to the backplane 10. The display panel 22 is formed on a side of the substrate 21 depart from the backplane 10.

Step S12, referring to FIG. 6, dispensing along a peripheral region of the back plate 10 to form an uncured or semi-cured sealant 40, so that the sealant 40 and the back plate 10 surround setting and form the receiving slot 70 to receive the display panel 20. The height of the sealant 40 is greater than the height of the display panel 20.

In the present embodiment, the sealant 40 may be a UV-curable adhesive or a thermosetting adhesive.

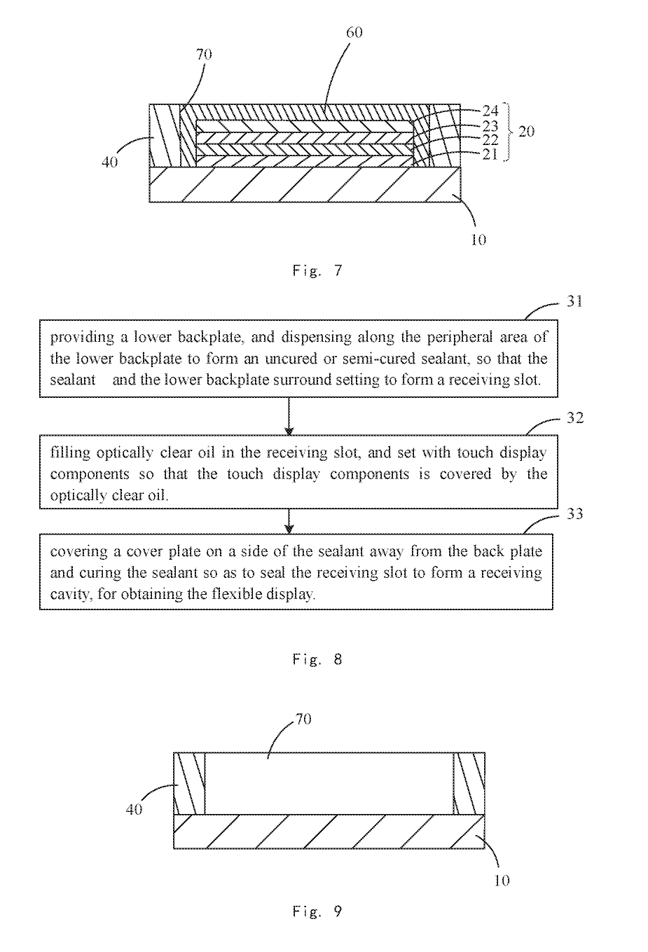

In step S13, referring to FIG. 7, at least an area of the receiving slot 70 corresponding to the folding region is filled with optically clear oil 60, so that at least the optically clear oil 60 covers the folding region.

Specifically, an optically clear adhesive may be coated on at least a part of the receiving slot 70 corresponding to the non-folded area so that the optical clear adhesive covers the corresponding non-folded region. Correspondingly, the receiving slot 70 corresponds to the region of the folding region and the region of the accommodating slot 70 corresponding to the non-folding region where the optically clear adhesive is not coated are filled with the optically clear oil 60 so that the optically clear oil 60 covers the folding region and the area optically clear plastic covered non-folded region. Or the accommodating slot 70 may be filled with optically clear oil 60 to cover the entire display panel 20.

In the present embodiment, the accommodating slot 70 is filled with optically clear oil 60 to cover the entire display panel 20.

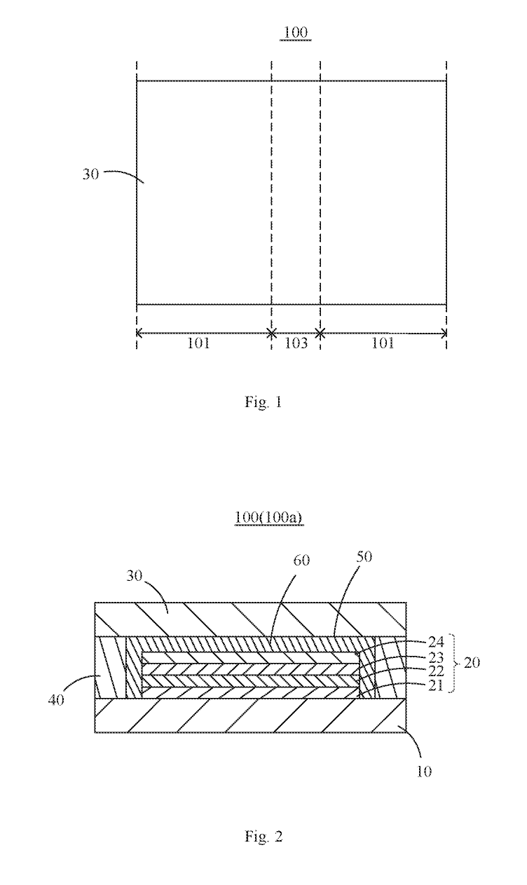

Step S14, referring to FIG. 2, covering a side of the sealant 40 away from the backplane 10 with a cover 30 and curing the sealant 40 to seal the receiving slot 70 to form a receiving cavity 50, Thereby manufacturing the flexible display 100a.

Specifically, in the evacuated state, the back plate 10 is sealed to the receiving slot 70 to form a sealed receiving cavity 50 so as to prevent air bubbles from being generated between the cover plate 30 and the optically clear oil 60, and the negative pressure is produced in the receiving chamber 50, so that the connection between the back plate 10, the cover plate 30 and the sealant 40 is more compact, thereby preventing the optically clear oil 60 from leaking out.

See FIG. 1, 3 8 to 10, another preferred embodiment of the present disclosure further provides a fabricating method of a flexible display 100b, which is divided into at least two non-bending regions 101 and a connection bending region 103 of two adjacent non-bending regions 101, the fabricating method of the flexible display 100 b comprises the following steps:

Step 31, referring to FIG. 9, provides a back plate 10 and dispensing along the peripheral region of the back plate 10 to form an uncured or semi-cured sealant 40, so that the sealant 40 and the back plate 10 surround setting to form a receiving slot 70.

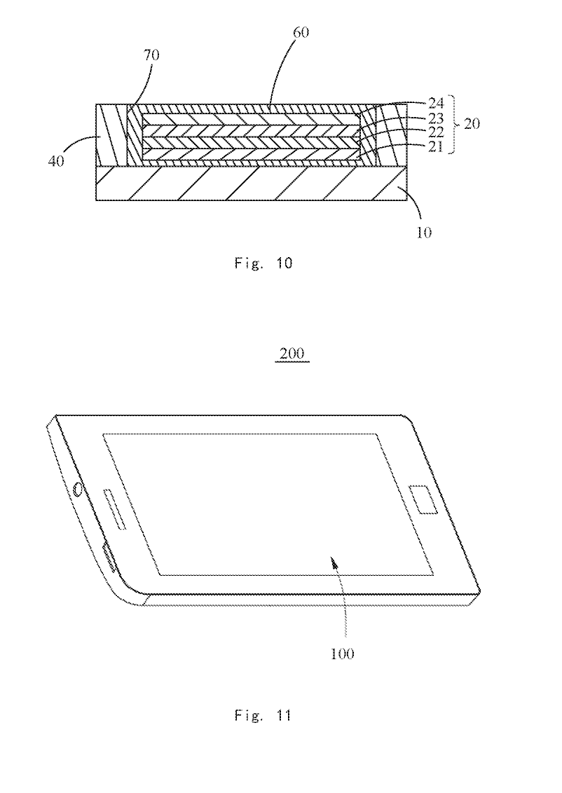

Step 32, referring to FIG. 10, filling the receiving slot 70 with the transparent optical oil 60, and placing the height of the display panel 20 is less than the depth of the receiving slot 70 so that the optically clear oil 60 covered the whole display panel 20.

Specifically, the receiving slot 70 can be directly filled with the transparent optically oil 60 enough to submerge the follow-up placed display panel 20. Or a part of the transparent optically oil may be filled in the receiving slot 70 to separate the follow-up placing display 20 and the back plate 10 through the transparent optically oil and after put in the display 20 then in the vacuum state continuously filled the optically clear oil so that the optically clear 60 in the receiving slot 70 covers the entire display panel 20.

Step S33, referring to FIG. 3, covering a side of the sealant 40 away from the backplane 10 with a cover plate 30 and curing the sealant 40 to seal the receiving slot 70 to form a receiving cavity 50, thereby fabricating the flexible display 100a.

Please refer to FIG. 11, which is a schematic diagram of the display device 200. The display device 200 includes the above flexible display 100 (100a, 100b). Wherein the display device 200 may be a cell phone, a tablet, a television, or the like.

In the flexible display 100 (100a, 100b) of the present disclosure, an optically clear oil 60 is disposed between a region of the display panel 20 corresponding to the bending region 103 and the cover plate 30, such that the flexible display 100 (100a, 100b), the display panel 20 and the cover plate 30 do not transmit the stress to each other during bending, and the display panel 20, the cover plate 30 and the optically clear oil 60 respectively have a neutral surface (Neutral Plane) such that the position of the neutral plane of the display panel 20 does not change after the flexible display 100 (100a, 100b) is formed, to avoid damage caused by the change of the neutral plane position of the display panel 20 when the flexible display 100 (100a, 100b) is folded. In addition, an optically clear oil 60 is disposed between a region of the display panel 20 corresponding to the bending region 103 and the cover plate 30, and the total reflectivity of light at each interface is also reduced, so as to improve the display panel 20 of the light output efficiency. Likewise, the formation of the optically clear oil 60 between the backplate 10 and the display panel 20 can further protect the display panel 20 when the flexible display 100 (100a, 100b) is folded so as to prevent the flexible display 100 (100a, 100b) from failing and facilitates the conduction of heat of the flexible display 100 (100a, 100b) to avoid local overheating of the flexible display 100 (100a, 100b).

The above disclosure is only the preferred embodiments of the present disclosure, and certainly cannot be used to limit the scope of the present disclosure. Those skilled in the art may understand that all or part of the processes of the above embodiments may be implemented and that the claims of the present disclosure equivalent changes are still within the scope of the disclosure.

What is claimed is:

1. A flexible display, wherein the flexible display is divided into at least two non-bending regions and a bending region of connecting two adjacent non-bending regions, the flexible display comprises a backplate, a display panel and a cover plate laminated in order, wherein a peripheral area of the backplate and a peripheral area of the cover plate are connected through a sealant and form a sealed receiving cavity between the backplate and the cover plate; the display panel is set on the backplate and received in the receiving cavity, an optically clear oil is provided between an area of the display panel corresponding to the bending region and the cover plate.

2. The flexible display according to claim 1, wherein the optically clear oil is provided between the area of the display panel corresponding to the bending region and the sealant, and the fluidity of the optically clear oil is favorable to describe heat dissipation of the flexible display to avoid local overheating of the flexible display.

3. The flexible display according to claim 2, wherein the optical clear oil is provided between the cover plate and an area of the display panel corresponding to the non-bending region, and is provided between the sealant and of the display panel corresponding to the non-bending region.

4. The flexible display according to claim 2, wherein the optical clear oil is disposed between an area of the display panel corresponding to the bending region and the backplate.

5. A fabricating method of a flexible display, wherein the flexible display is divided into at least two non-bending regions and a bending region of connecting two adjacent non-bending regions, the fabricating method of the flexible display device comprises the following steps:
providing a backplate bonded with a display panel, the display panel comprising a non-folding region corresponding to the non-bending region, and a folding region corresponding to the bending region;
forming an uncured or semi-cured sealant along a peripheral region of the back plate, so that the sealant and the back plate enclosed to form a receiving slot for receiving the display panel, wherein and height of the sealant is greater than height of the display panel;
filling optically clear oil at least in an area of the receiving slot corresponding to the folding region, so that the optically clear oil at least covering the folding region; and
covering a side of the sealant away from the back plate with a cover plate and curing the sealant, so as to seal the receiving slot to form a receiving cavity for fabricating the flexible display.

6. The fabricating method of the flexible display according to claim 5, wherein the step of filling optically clear oil at least in the area of the receiving slot corresponding to the folding region, so that the optically clear oil at least covering the folding region further comprises:
filling the optically clear oil to cover the display panel entirely.

7. The fabricating method of a flexible display according to claim 5, wherein the step of filling the optically clear oil at least in the area of the receiving slot corresponding to the folding region, so that the optically transparent clear oil at least covering the folding region further comprises:
coating an optically clear adhesive on at least a portion of the receiving slot corresponding to the non-folding region, so that the optically clear adhesive covering the corresponding non-folding region; and
filling an optically clear oil in an area of the receiving slot corresponding to the folding region and an area of the receiving slot corresponding to the non-folding region where the optically clear oil is not coated, so that the optically clear oil covering the folding region and the non-folding region where the optically clear oil is not coated.

8. A display device, comprising a flexible display divided into at least two non-bending regions and bending regions of connecting two adjacent non-bent regions, the flexible display comprising a backplate, a display panel and a cover plate laminated in order, a peripheral region of the backplate and a peripheral region of the cover plate are connected through a sealant and form a sealed receiving cavity between the back plate and the cover plate, the display panel is set on the backplate and received in the receiving cavity, and an optically clear oil is provided between the cover plate and a region of the display panel corresponding to the bending region.

9. The display device according to claim 8, wherein: an optically clear oil is provided between the sealant and a region of the display panel corresponding to the bending region and the sealant, the fluidity of the optically clear oil facilitates heat dissipation of the flexible display to avoid the flexible display local overheating.

10. The display device according to claim 9, wherein the optically clear oil is provided between a region of the display panel correspond to the non-bending region and the cover plate, and between a region of the display panel correspond to a non-bending region and the sealant.

11. The display device according to claim 9, wherein an optically clear oil is provided between a region of the display panel corresponding to the bending region and the backplate.
